(19) United States
(12) Patent Application Publication
(10) Pub. No.: US 2022/0017673 A1
(43) Pub. Date: Jan. 20, 2022

(54) Dielectric Film Forming Compositions

(71) Applicant: Fujifilm Electronic Materials U.S.A., Inc., N. Kingstown, RI (US)

(72) Inventors: Sanjay Malik, Attleboro, MA (US); Binod B. De, Attleboro, MA (US); William A. Reinerth, Riverside, RI (US); Ognian Dimov, Warwick, RI (US); Stephanie Dilocker, Attleboro, MA (US)

(21) Appl. No.: 17/373,827

(22) Filed: Jul. 13, 2021

Related U.S. Application Data
(60) Provisional application No. 63/052,063, filed on Jul. 15, 2020.

(51) Int. Cl. C08F 283/04; H01L 23/00; G03F 7/004; G03F 7/037; G03F 7/00

(52) U.S. Cl. CPC C08F 283/04; H01L 24/27; H01L 24/29; G03F 7/0047; G03F 7/037; H01L 2224/2979; H01L 2924/12041; H01L 2224/27436; H01L 2224/29147; H01L 2224/2969; G03F 7/0037

(57) ABSTRACT

This disclosure relates to a dielectric film forming composition that includes a plurality of (meth)acrylate containing compounds, at least one fully imidized polyimide polymer, and at least one solvent.

### CROSS-REFERENCE TO RELATED APPLICATION

The present application claims priority to U.S. Provisional Application Ser. No. 63/052,063, filed on Jul. 15, 2020, the contents of which are hereby incorporated by reference in their entirety.

### BACKGROUND OF THE DISCLOSURE

Dielectric material requirements for semiconductor packaging applications are continuously evolving. New, advanced devices are relying heavily on wafer and panel-level packaging (WLP and PLP) and 3D heterogeneous integration. While there are a number of traditional dielectric materials that have been employed through the years, polyimides, due to their excellent electrical, mechanical and thermal properties, have been the material of choice for semiconductor packaging applications. Drawbacks of conventional polyimides include high cure temperatures (>350° C.), high post-cure (thermal) shrinkage and high levels of moisture absorption. The high cure temperature requirement for polyimides (PI) poses limitation on its usage for panel-level manufacturing as the plastic core employed in panel manufacturing cannot withstand temperatures higher than about 250° C. The high shrinkage of conventional polyimides leads to cured films having high residual stress which leads to bowing of the silicon wafer and warpage of the plastic core.

The trend in electronic packaging continues to be towards smaller feature sizes, faster processing speeds, increased complexity, higher power and lower cost. Reliability of the semiconductor package and its constituent materials has become an increasingly important factor for IC manufacturers as advanced packages are finding diverse, new applications in the area of microprocessors and wireless telecommunications. This makes selecting dielectric materials with superior reliability of paramount importance in fabricating advanced packages.

The mechanical properties of polyimides, especially elongation to break (Eb), are particularly important for insuring the long term reliability of the microelectronic device. Next generation dielectric materials must be designed so as to be both tough and flexible. This is required to effectively insulate the conducting features of a microelectronic device without cracking.

The low temperature cured photosensitive resin composition (e.g. less than 200° C.) with good chemical and moisture resistance have been described in Japanese patent applications No JP2020056957 and JP2020056597 and PCT application No WO20070924 where a crosslinkable monomer upon exposure is reacted with a polyimide precursor polymer having a polymerizable moiety. The attachment of crosslinkable monomer with polyimide precursor having a polymerizable moiety reduces toughness of material by reducing elongation to break (% Eb) of the resulting film. Moreover, the higher thermal shrinkage during cyclization of polyimide precursor having a polymerizable moiety also strongly affect the reliability of these photosensitive dielectric materials based films.

### SUMMARY OF THE DISCLOSURE

This disclosure describes dielectric film forming compositions that include (meth)acrylate containing compounds and a fully imidized polyimide polymer. These compositions can be photosensitive and can form dielectric films having improved mechanical properties, thermal shrinkage, and reliability by, e.g., forming an interpenetrating network involving fully cyclized polyimide.

In one aspect, this disclosure features a dielectric film forming composition that includes:

a. a plurality of (meth)acrylate containing compounds containing

i) at least one mono(meth)acrylate containing compound of structure (I),

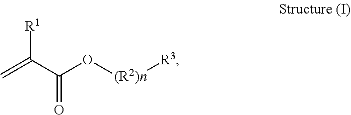

in which R¹ is a hydrogen atom, a C₁-C₃ alkyl group, a fully or partially halogen substituted C₁-C₃ alkyl group, or a halogen atom; R² is a C₂-C₁₀ alkylene group, a C₅-C₂₀ cycloalkylene group, or a R⁴O group, in which R⁴ is a linear or branched C₂-C₁₀ alkylene group or a C₅-C₂₀ cycloalkylene group; R³ is a substituted or unsubstituted linear, branched or cyclic C₁-C₁₀ alkyl group, a saturated or unsaturated C₅-C₂₅ (e.g., C₇-C₂₅) alicyclic group, a C₆-C₁₅ aryl group, or a C₇-C₁₅ alkylaryl group; and n=0 or 1;

ii) at least one di(meth)acrylate containing cross linker; and

iii) optionally at least one multi(meth)acrylate containing cross linker comprising at least 3 (meth)acrylate groups;

b. at least one fully imidized polyimide polymer; and

c. optionally, at least one solvent.

In another aspect, this disclosure features a process that includes (a) coating a substrate with the dielectric film forming composition described herein to form a coated substrate having a film on the substrate, and (b) baking the coated substrate to form a coated substrate having a dried film.

In another aspect, this disclosure features a process that includes (a) coating a carrier substrate with the dielectric film forming composition described herein to form a coated composition; (b) drying the coated composition to form a photosensitive polyimide layer; and (c) optionally applying a protective layer to the photosensitive polyimide layer to form a dry film structure.

In another aspect, this disclosure features a process that includes applying the dry film structure described herein onto an electronic substrate to form a laminate, in which the photosensitive polyimide layer in the laminate is between the electronic substrate and the carrier substrate.

In another aspect, this disclosure features a process of generating a photosensitive polyimide film on a substrate having a copper pattern. The process includes depositing the dielectric film forming composition described herein onto a substrate having a copper pattern to form a photosensitive polyimide film, in which the difference in the highest and lowest points on a surface of the photosensitive polyimide film is at most about 2 microns.

In another aspect, the disclosure features a patterned dielectric film produced by the dielectric film forming composition described herein. In some embodiments, the patterned dielectric film is produced by: a) depositing a dielectric film forming composition described herein on a substrate to form a dielectric film; and b) patterning the dielectric film by a lithographic method or by a laser ablation method.

In another aspect, the disclosure features a three dimensional object that includes at least one patterned dielectric film (e.g., those formed by the process described herein) and at least one substrate. In some embodiments, the substrate includes an organic film, an epoxy molded compound (EMC), silicon, glass, copper, stainless steel, copper cladded laminate (CCL), aluminum, silicon oxide, silicon nitride, or a combination thereof. In some embodiments, the substrate comprises a metal pattern. In some embodiments, the patterned dielectric film comprises surrounding copper patterns.

In another aspect, the disclosure features a process for preparing a three dimensional, the process including: a) depositing a dielectric film forming composition described herein on a substrate to form a dielectric film; b) exposing the dielectric film to radiation or heat or a combination of radiation or heat; c) patterning the dielectric film to form a patterned dielectric film having openings; d) optionally depositing a seed layer on the patterned dielectric film; and e) depositing a metal layer in at least one opening in the patterned dielectric film to form a metal pattern.

In another aspect, the disclosure features a process for forming a three dimensional object, the process including: a) providing a substrate containing copper conducting metal wire structures that form a network of lines and interconnects on the substrate; b) depositing a dielectric film forming composition described herein on the substrate to form a dielectric film; and c) exposing the dielectric film to radiation or heat or a combination of radiation and heat.

In another aspect, the disclosure features a semiconductor device that includes the three dimensional object described herein.

In another aspect, the disclosure features a dry film prepared by the dielectric film forming composition described herein.

In yet another aspect, the disclosure features a process for preparing a dry film structure, the process including: (a) coating a carrier substrate with a dielectric film forming composition described herein to form a coated composition; (b) drying the coated composition to form a photosensitive polyimide layer; and (c) optionally applying a protective layer to the photosensitive polyimide layer to form a dry film structure. In such embodiments, the process can further include applying the dry film structure thus obtained onto an electronic substrate to form a laminate, wherein the photosensitive polyimide layer in the laminate is between the electronic substrate and the carrier substrate.

### BRIEF DESCRIPTION OF THE DRAWINGS

FIG. 1A: Optical microscope image 10/10 micron line/space at 20 times magnification after 210 hours of Highly Accelerated Stress Test (HAST) for Reliability Test Example 1.

FIG. 1B: Cross-sectional SEM by using Hitachi S4800 at 2.0 kV at 2200 times magnification after 210 hours of HAST for Reliability Test Example 1.

FIG. 2A: Optical microscope image 10/10 micron line/space at 20 times magnification after 210 hours of HAST for Reliability Test Comparative Example 1.

FIG. 2B: Cross-sectional SEM by using Hitachi S4800 at 2.0 kV at 2200 times magnification after 210 hours of HAST for Reliability Test Comparative Example 1.

### DETAILED DESCRIPTION OF THE DISCLOSURE

As used herein, the term “fully imidized” means the polyimide polymers of this disclosure are at least about 90% (e.g., at least about 95%, at least about 98%, at least about 99%, or about 100%) imidized. As used herein, the term “(meth)acrylates” include both acrylates and methacrylates. As used herein, a catalyst (e.g., an initiator) is a compound capable of inducing a polymerization or crosslinking reaction when exposed to heat and/or a source of radiation. As used herein, an electronic substrate is a substrate (e.g., a silicon or copper substrate or wafer) that becomes a part of a final electronic device. As used herein, the terms “film” and “layer” are used interchangeably.

Some embodiments of this disclosure describe a dielectric film forming composition that includes:

a) a plurality of (meth)acrylate containing compounds containing:

i) at least one mono(meth)acrylate containing compound of Structure (I),

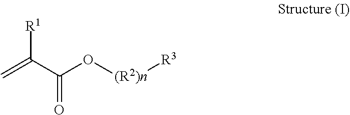

in which R¹ is a hydrogen atom, a C₁-C₃ alkyl group, a fully or partially halogen substituted C₁-C₃ alkyl group, or a halogen atom; R² is a C₂-C₁₀ alkylene group, a C₅-C₂₀ cycloalkylene group, or a R⁴O group, in which R⁴ is a linear or branched C₂-C₁₀ alkylene group or a C₅-C₂₀ cycloalkylene group; R³ is a substituted or unsubstituted linear, branched or cyclic C₁-C₁₀ alkyl group, a saturated or unsaturated C₅-C₂₅ (e.g., C₇-C₂₅) alicyclic group, a C₆-C₁₈ aryl group, or a C₇-C₁₈ alkylaryl group; and n is 0 or 1;

ii) at least one di(meth)acrylate containing cross linker; and

iii) optionally at least one multi(meth)acrylate containing cross linker containing at least 3 (meth)acrylate groups;

b) at least one fully imidized polyimide polymer; and

c) optionally, at least one solvent.

Suitable examples of R¹ groups include, but are not limited to, methyl, ethyl, propyl, isopropyl, chloro, fluoro, bromo, trifluoromethyl and the like.

Suitable examples of R² include, but are not limited to, ethylene, propylene, butylene, isopropylidene, isobutylene, hexylene, ethylenoxy, propylenoxy, butylenoxy, isopropylenoxy, cyclohexylenoxy, diethyleneglycoloxy, triethyleneglycoloxy and the like.

Suitable examples of R³ include, but are not limited to, phenyl, cyclohexyl, bornyl, isobornyl, dicyclopentenyloxyethyl, dicyclopentenyl, dicyclopentanyloxyethyl, dicyclopentanyl, 3a,4,5,6,7,7a-hexahydro-1H-4,7-ethanoinden-6-yl, 2-[(3a,4,5,6,7,7a-hexahydro-1H-4,7-ethanoinden-6-yl)oxy]ethyl, tricyclo[5,2,1,0^{2,6}]decyl, tricyclo[5,2,1,0^{2,6}]decanemethyl, tetracyclo[4,4,0,1^{2,5},1^{7,10}]dodecanyl, and the like.

Illustrative examples of mono(meth)acrylate containing compound of Structure (I) include, but are not limited to, cyclohexyl acrylate, cyclohexyl methacrylate, 2-butoxyethyl acrylate, 2-phenoxyethyl acrylate, ethylene glycol phenyl ether acrylate, nonylphenoxyethyl acrylate, bornyl acrylate, isobornyl acrylate, isobornyl methacrylate, tetrahydrofurfuryl acrylate, tetrahydrofurfuryl methacrylate, dicyclopentenyloxyethyl acrylate, dicyclopentenyl acrylate, dicyclopentenyloxyethyl trifluoromethylacrylate, dicyclopentenyl trifluoromethylacrylate, dicyclopentanyl acrylate, dicyclopentenyloxyethyl methacrylate, dicyclopentenyl methacrylate, dicyclopentanyl methacrylate, methoxypolyethyleneglycol methacrylate, ethylene glycol dicyclopentenyl ether acrylate, bicyclo[2.2.2]oct-5-en-2-yl acrylate, bicyclo[2.2.2]oct-5-en-2-yl methacrylate, 2-[(bicyclo[2.2.2]oct-5-en-2-yl)oxy]ethyl acrylate, 2-[(bicyclo[2.2.2]oct-5-en-2-yl)oxy]ethyl methacrylate, 3a,4,5,6,7,7a-hexahydro-1H-4,7-ethanoinden-6-yl acrylate, 3a,4,5,6,7,7a-hexahydro-1H-4,7-ethanoinden-6-yl methacrylate, 2-[(3a,4,5,6,7,7a-hexahydro-1H-4,7-ethanoinden-6-yl)oxy]ethyl acrylate, 2-[(3a,4,5,6,7,7a-hexahydro-1H-4,7-ethanoinden-6-yl)oxy]ethyl methacrylate, tricyclo[5,2,1,0^{2,6}]decyl acrylate, tricyclo[5,2,1,0^{2,6}]decyl methacrylate, tricyclo[5,2,1,0^{2,6}]decylmethyl acrylate, tricyclo[5,2,1,0^{2,6}]decanemethyl methacrylate, tetracyclo[4,4,0,1^{2,5},1^{7,10}]dodecanyl acrylate, tetracyclo[4,4,0,1^{2,5},1^{7,10}]dodecanyl methacrylate and the like.

More preferred examples of mono(meth)acrylate containing compounds of Structure (I) include those shown in Structures (I-A) to (I-D):

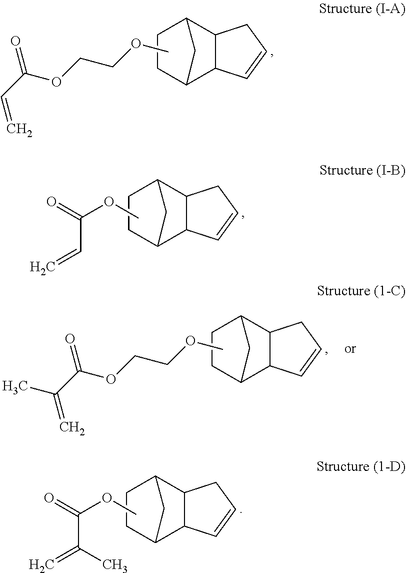

In some embodiments, the dielectric film forming composition described herein can include a single or mixture (e.g., two or three) of mono(meth)acrylate containing compounds, each having a boiling point of at least about 180° C. (e.g., at least about 200° C. or at least about 250° C.) at normal atmospheric pressure. Advantageously, this may aid to prevent the mono(meth)acrylate from evaporating out of the dielectric film during a film processing step which involves a baking step, such as dry film coating on a PET film or spin coating on a wafer of a coating prepared from the dielectric composition. Cyclohexyl methacrylate with boiling point of 210° C. at atmospheric pressure is an example of a mono(meth)acrylate with boiling point higher than 200° C. and isobornyl methacrylate with boiling point of 263° C. at atmospheric pressure is an example of a mono(meth)acrylate with boiling point higher than 250° C.

In some embodiments, the amount of the mono(meth)acrylate containing compound of Structure (I) is at least about 1 weight % (e.g., at least about 3 weight %, at least about 5 weight %, at least about 7 weight %, at least about 9 weight %, at least about 10 weight %, at least about 11 weight %, at least about 13 weight %, at least 15 weight %, at least about 17 weight %, or at least about 20 weight %) and/or at most about 50 weight % (e.g., at most about 45 weight %, at most about 40 weight %, at most about 35 weight %, at most about 30 weight % or at most about 25 weight %) of the total weight of the plurality of (meth)acrylate containing compounds.

In some embodiments, the amount of the mono(meth)acrylate containing compound of Structure (I) is at least about 0.1 weight % (e.g., at least about 0.2 weight %, at least about 0.3 weight % at least about 0.4 weight %, at least about 0.5 weight %, at least about 0.6 weight %, at least about 0.7 weight %, at least 0.8 weight %, at least about 0.9 weight %, or at least about 1 weight %) and/or at most about 10 weight % (e.g., at most about 9 weight %, at most about 7 weight %, at most about 5 weight %, at most about 3 weight %, or at most about 2 weight %) of the total weight of the dielectric film forming composition.

Without wishing to be bound by theory, it is believed that the presence of at least one mono(meth)acrylate containing compound of Structure (I) can enhance the lifetime of the final semiconductor device prepared by the dielectric film forming composition described herein. In some embodiments, reliability testing can be used to predict or estimate useful device lifetime. For example, unbiased highly accelerated stress test (uHAST) is a method of measuring effects of temperature and humidity on photosensitive interlayer dielectric (PID) in the presence of copper structures (e.g., no current applied, 130° C., 85% relative humidity (RH), typically 96-168 hours). A PID that has good reliability will not crack or lift away from a copper structure or substrate under unbiased HAST conditions. Without wishing to be bound by theory, it is believed that a dielectric film prepared from at least one mono(meth)acrylate containing compound of Structure (I) can avoid cracking or lifting away from a copper structure or substrate under unbiased HAST conditions.

Examples of at di(meth)acrylate containing cross linker include, but are not limited to, 1,3-butylene glycol di(meth)acrylate, 1,4-butanediol di(meth)acrylate, 1,5-pentanediol di(meth)acrylate, 1,6-hexanediol di(meth)acrylate, 1,9-nonanediol di(meth)acrylate, 1,10-decanediol di(meth)acrylate, 1,12-dodecanediol di(meth)acrylate, tetraethylene glycol di(meth)acrylate, cyclohexane dimethanol di(meth)acrylate, polyethylene glycol di(meth)acrylate, ethylene glycol di(meth)acrylate, polyethylene glycol di(meth)acrylate, diurethane di(meth)acrylate, 1,4-phenylene di(meth)acrylate, 2,2-bis[4-(2-hydroxy-3-methacryloxypropoxy)phenyl]propane, bis(2-hydroxyethyl)-isocyanurate di(meth)acrylate, neopentyl glycol di(meth)acrylate, and tricyclodecane dimethanol di(meth)acrylate.

In some embodiments, the amount of the at least one di(meth)acrylate containing cross linker is at least about 20 weight % (e.g., at least about 25 weight %, at least about 30 weight %, at least about 35 weight %, at least about 40 weight %, or at least 45 weight %) and/or at most about 85 weight % (e.g., at most about 80 weight %, at most about 75 weight %, at most about 70 weight %, at most about 65 weight %, at most about 60 weight %, or at most about 55 weight %) of the total weight of the plurality of (meth)acrylate containing compounds.

In some embodiments, the amount of the at least one di(meth)acrylate containing cross linker is at least about 3 weight % (e.g., at least about 5 weight %, at least about 7 weight %, or at least 10 weight %) and/or at most about 30 weight % (e.g., at most about 25 weight %, at most about 20 weight %, or at most about 15 weight %) of the total weight of the dielectric film forming composition. Without wishing to be bound by theory, it is believed that the di(meth)acrylate containing cross linker can be crosslinked upon exposure to a radiation and heat source to form a negative tone polyimide film that can be patterned to form a relief image during a semiconductor manufacturing process. In other words, including the di(meth)acrylate containing cross linker into the dielectric film forming composition described herein can be impart photosensitivity to the composition.

Examples of optional multi(meth)acrylate containing cross linker having at least 3 (meth)acrylate groups include, but are not limited to, propoxylated (3) glycerol tri(meth)acrylate, pentaerythritol tetra(meth)acrylate, pentaerythritol tri(meth)acrylate, dipentaerythritol penta-/hexa-(meth)acrylate, isocyanurate tri(meth)acrylate, ethoxylated glycerine tri(meth)acrylate, trimethylol propane tri(meth)acrylate, ditrimethylol propane tetra(meth)acrylate, ethoxylated pentaerythritol tetra(meth)acrylate, tetramethylol methane tetra(meth)acrylate, 1,2,4-butanetriol tri(meth)acrylate, diglycerol tri(meth)acrylate, trimethylol propane ethoxylate tri(meth)acrylate, trimethylol propane polyethoxylate tri(meth)acrylate, tetramethylolmethane tetra(meth)acrylate, and tris(2-hydroxyethyl)isocyanurate triacrylate.

In some embodiments, if used, the amount of the at least one multi(meth)acrylate containing cross linker having at least 3 (meth)acrylate groups is at least about 5 weight % (e.g., at least about 7 weight %, at least about 10 weight %, at least about 15 weight %, or at least 20 weight %) and/or at most about 40 weight % (e.g., at most about 35 weight %, at most about 32 weight %, at most about 30 weight %, at most about 28 weight %, or at most about 25 weight %) of the total weight of the plurality of (meth)acrylate containing compounds.

In some embodiments, if used, the amount of the at least one multi(meth)acrylate containing cross linker having at least 3 (meth)acrylate groups is at least about 1 weight % (e.g., at least about 2 weight %, at least about 3 weight %, at least about 4 weight %, or at least 5 weight %) and/or at most about 10 weight % (e.g., at most about 9 weight %, at most about 8 weight %, at most about 7 weight %, or at most about 6 weight %) of the total weight of the dielectric film forming composition. Without wishing to be bound by theory, it is believed that the multi(meth)acrylate containing cross linker can be crosslinked upon exposure to a radiation and heat source to help forming a negative tone polyimide film that can be patterned to form a relief image during a semiconductor manufacturing process. In other words, including the multi(meth)acrylate containing cross linker into the dielectric film forming composition described herein can be facilitate imparting photosensitivity to the composition.

In some embodiments, the total amount of the plurality of (meth)acrylate containing compounds is at least about 1 weight % (e.g., at least about 2 weight %, at least about 4 weight %, at least about 8 weight %, at least about 12 weight %, or at least about 16 weight %) and/or at most about 50 weight % (e.g., at most about 45 weight %, at most about 40 weight %, at most about 35 weight %, at most about 30 weight %, or at most about 20 weight %) of the total weight of the dielectric film forming composition.

In some embodiments, the at least one fully imidized polyimide polymer of the dielectric film forming composition is prepared by reaction of at least one diamine with at least one dicarboxylic acid dianhydride.

Examples of suitable diamines include, but are not limited to, 1-(4-aminophenyl)-1,3,3-trimethylindan-5-amine (alternative names including 4,4′-[1,4-phenylene-bis(1-methylethylidene)] bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfones, 4,4′-isopropylidenedianiline, 4,4′-diaminodiphenylmethane, 2,2-bis(4-aminophenyl)propane, 4,4′ diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis(trifluoromethyl) benzidine, 3,3′-bis(trifluoromethyl) benzidine, 2,2-bis[4-(4-aminophenoxy phenyl)] hexafluoropropane, 2,2-bis(3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline)isopropylidene, bis(p-beta-amino-t-butylphenyl)ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl] propane, 4,4′-[1,3-phenylenebis(1-methyl-ethylidene)] bisaniline, 4,4′-[1,4-phenylenebis(1-methyl-ethylidene)]bisaniline, 2,2-bis[4-(4-aminophenoxy) phenyl] sulfone, 2,2-bis[4-(3-aminophenoxy) benzene], 1,4-bis(4-aminophenoxy) benzene, 1,3-bis(4-aminophenoxy) benzene, 1,3′-bis(3-aminophenoxy) benzene, and 9H-fluorene-2,6-diamine. Any of these diamines can be used individually or in combination in any ratio as long as the resulting polyimide polymer satisfies the requirements of this disclosure.

Examples of tetracarboxylic acid dianhydride monomers include, but are not limited to, 1-(3′,4′-dicarboxyphenyl)-1,3,3-trimethylindan-5,6-dicarboxylic acid dianhydride, 1-(3′,4′-dicarboxyphenyl)-1,3,3-trimethylindan-6,7-dicarboxylic acid dianhydride, 1-(3′,4′-dicarboxyphenyl)-3-methylindan-5,6-dicarboxylic acid dianhydride, 1-(3′,4′-dicarboxyphenyl)-3-methylindan-6,7-dicarboxylic acid anhydride, pyrazine-2,3,5,6-tetracarboxylic dianhydride, thiophene-2,3,4,5-tetracarboxylic dianhydride, 2,3,5,6-pyridinetetracarboxylic acid dianhydride, norbornane-2,3,5,6-tetracarboxylic acid dianhydride, bicyclo[2.2.2]oct-7-ene-3,4,8,9-tetracarboxylic acid dianhydride, tetracyclo[4.4.1.0^{2,5}.0^{7,10}]undecane-1,2,3,4-tetracarboxylic acid dianhydride, 3,3′,4,4′-benzophenone tetracarboxylic dianhydride, 3,3′,4,4′-diphenylsulfone tetracarboxylic dianhydride, 3,3′,4,4′-diphenyl ether tetracarboxylic dianhydride, 2,3,3′,4′-diphenyl ether tetracarboxylic dianhydride, 2,2-[bis(3, 4-dicarboxyphenyl)] hexafluoropropane dianhydride, ethyleneglycol bis(anhydrotrimellitate), and 5-(2,5-dioxotetrahydro)-3-methyl-3-cyclohexene-1,2-dicarboxylic anhydride. More preferred tetracarboxylic acid dianhydride monomers include 2,2-[bis(3, 4-dicarboxyphenyl)] hexafluoropropane dianhydride, 3,3′,4,4′-benzophenone tetracarboxylic dianhydride, 3,3′,4,4′-diphenylsulfone tetracarboxylic dianhydride, and 3,3′,4,4′-diphenyl ether tetracarboxylic dianhydride. Any of these tetracarboxylic acid dianhydride can be used individually or in combination in any ratio as long as the resulting polyimide polymer satisfies the requirements of this disclosure.

Methods to synthesize polyimide polymers (e.g. fully imidized polyimide polymers) are well known to those skilled in the art. Examples of such methods are disclosed in, e.g., U.S. Pat. Nos. 2,731,447, 3,435,002, 3,856,752, 3,983,092, 4,026,876, 4,040,831, 4,579,809, 4,629,777, 4,656,116, 4,960,860, 4,985,529, 5,006,611, 5,122,436, 5,252,534, 5,478,915, 5,773,559, 5,783,656, 5,969,055, and 9,617,386, and US application publication numbers US20040265731, US20040235992, and US2007083016, the contents of which are hereby incorporated by reference.

In some embodiments, the weight average molecular weight (Mw) of the polyimide polymer described herein is at least about 5,000 Daltons (e.g., at least about 10,000 Daltons, at least about 20,000 Daltons, at least about 25,000 Daltons, at least about 30,000 Daltons, at least about 35,000 Daltons, at least about 40,000 Daltons, or at least about 45,000 Daltons) and/or at most about 100,000 Daltons (e.g., at most about 90,000 Daltons, at most about 80,000 Daltons at most about 70,000 Daltons, at most about 65,000 Daltons, at most about 60,000 Daltons, at most about 55,000 Daltons, or at most about 50,000 Daltons). In some embodiments, the weight average molecular weight (Mw) of the fully imidized polyimide polymer is from about 20,000 Daltons to about 70,000 Daltons or from about 30,000 Daltons to about 80,000 Daltons. The weight average molecular weight can be obtained by gel permeation chromatography methods and calculated using a polystyrene standard.

The preferred fully imidized polyimide polymers are those without any polymerizing moiety attached to the polymer.

In some embodiments, the amount of the fully imidized polyimide polymer is at least about 2 weight % (e.g., at least about 5 weight %, at least about 10 weight %, at least about 15 weight %, or at least about 20 weight %) and/or at most about 55 weight % (e.g., at most about 50 weight %, at most about 45 weight %, at most about 40 weight %, at most about 35 weight %, at most about 30 weight %, or at most about 25 weight %) of the total amount of the dielectric film forming composition.

In some embodiments, the dielectric film forming composition can include at least one (e.g., two, three, or four) solvent (e.g., an organic solvent). Examples of suitable organic solvents include, but are not limited to, alkylene carbonates such as ethylene carbonate, propylene carbonate, butylene carbonate, and glycerine carbonate; lactones such as gamma-butyrolactone, ε-caprolactone, γ-caprolactone and δ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; glycol esters such as propylene glycol methyl ether acetate; glycol ethers such as propylene glycol methyl ether (PGME); cyclic ethers such as tetrahydrofuran (THF); and pyrrolidones such as n-methyl pyrrolidone (NMP).

In a preferred embodiment, the solvent of the dielectric film forming composition can contain alkylene carbonates such as ethylene carbonate, propylene carbonate, butylene carbonate, glycerine carbonate, or a combination thereof. In some embodiments, the amount of alkylene carbonate is at least about 20 weight % (e.g., at least about 30 weight %, at least about 40 weight %, at least about 50 weight %, at least about 60 weight %, at least about 70 weight %, at least 80 weight %, or at least about 90 weight %) of the dielectric film forming composition. Without wishing to be bound by theory, it is believed that a carbonate solvent (e.g., ethylene carbonate, propylene carbonate, butylene carbonate or glycerine carbonate) can facilitate the formation of a photosensitive polyimide film or a dielectric film with a planarized surface (e.g., the difference in the highest and lowest points on a top surface of the photosensitive polyimide film or a dielectric film is less than about 2 microns).

In some embodiments, the amount of the solvent is at least about 40 weight % (e.g., at least about 45 weight %, at least about 50 weight %, at least about 55 weight %, at least about 60 weight %, or at least about 65 weight %) and/or at most about 98 weight % (e.g., at most about 95 weight %, at most about 90 weight %, at most about 85 weight %, at most about 80 weight %, or at most about 75 weight %) of the total weight of the dielectric film forming composition.

In some embodiments, the dielectric film forming composition of this disclosure can include at least one (e.g., two, three, or four) catalyst (e.g., an initiator). The catalyst is capable of inducing crosslinking or polymerization reaction when exposed to heat (e.g., when the catalyst is a thermal initiator) and/or a source of radiation (e.g., when the catalyst is a photoinitiator).

Specific examples of photoinitiators include, but are not limited to, 1,8-octanedione, 1,8-bis[9-(2-ethylhexyl)-6-nitro-9H-carbazol-3-yl]-1,8-bis(0-acetyloxime), 2-hydroxy-2-methyl-1-phenylpropan-1-one, 1-hydroxycyclohexyl phenyl ketone (Irgacure 184 from BASF), a blend of 1-hydroxycyclohexylphenylketone and benzophenone (Irgacure 500 from BASF), 2,4,4-trimethylpentyl phosphine oxide (Irgacure 1800, 1850, and 1700 from BASF), 2,2-dimethoxyl-2-acetophenone (Irgacure 651 from BASF), bis(2,4,6-trimethyl benzoyl)phenyl phosphine oxide (Irgacure 819 from BASF), 2-methyl-1-[4-(methylthio)phenyl]-2-morphorinopropane-1-on (Irgacure 907 from BASF), (2,4,6-trimethylbenzoyl)diphenyl phosphine oxide (Lucerin TPO from BASF), 2-(Benzoyloxyimino)-1-[4-(phenylthio)phenyl]-1-octanone (Irgacure OXE-01 from BASF), 1-[9-Ethyl-6-(2-methylbenzoyl)-9H-carbazol-3-yl]ethanone 1-(0-acetyloxime) (Irgacure OXE-2 from BASF), ethoxy(2,4,6-trimethylbenzoyl)phenyl phosphine oxide (Lucerin TPO-L from BASF), a blend of phosphine oxide, hydroxy ketone and a benzophenone derivative (ESACURE KT046 from Arkema), 2-hydroxy-2-methyl-1-phenylpropane-1-on (Darocur 1173 from Merck), NCI-831 (ADEKA Corp.), NCI-930 (ADEKA Corp.), N-1919 (ADEKA Corp.), benzophenone, 2-chlorothioxanthone, 2-methylthioxanthone, 2-isopropylthioxanthone, benzodimethyl ketal, 1,1,1-trichloroacetophenone, diethoxyacetophenone, m-chloroacetophenone, propiophenone, anthraquinone, dibenzosuberone and the like.

In some embodiments, a photosensitizer can be used in the dielectric film forming composition where the photosensitizer can absorb light in the wavelength range of 193 to 405 nm. Examples of photosensitizers include, but are not limited to, 9-methylanthracene, anthracenemethanol, acenaphthylene, thioxanthone, methyl-2-naphthyl ketone, 4-acetylbiphenyl, and 1,2-benzofluorene.

Specific examples of thermal initiators include, but are not limited to, benzoyl peroxide, cyclohexanone peroxide, lauroyl peroxide, tert-amyl peroxybenzoate, tert-butyl hydroperoxide, di(tert-butyl)peroxide, dicumyl peroxide, cumene hydroperoxide, succinic acid peroxide, di(n-propyl)peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

In some embodiments, the amount of the catalyst is at least about 0.2 weight % (e.g., at least about 0.5 weight %, at least about 0.8 weight %, at least about 1.0 weight %, or at least about 1.5 weight %) and/or at most about 3.0 weight % (e.g., at most about 2.8 weight %, at most about 2.6 weight %, at most about 2.3 weight %, or at most about 2.0 weight %) of the total weight of the dielectric film forming composition.

In some embodiments, the dielectric film forming composition optionally includes one or more (e.g., two, three, or four) inorganic filler. In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. Preferably, the inorganic fillers are in a granular form of an average size of about 0.1-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (Ni₃Fe), Wairaruite (CoFe), Co₁₇Sm₂, and Nd₂Fe₁₄B.

In some embodiments, the amount of the inorganic filler (e.g., silica filler) is at least about 1 weight % (e.g., at least about 2 weight %, at least about 5 weight %, at least about 8 weight %, or at least about 10 weight %) and/or at most about 30 weight % (e.g., at most about 25 weight %, at most about 20 weight %, or at most about 15 weight %) of the total weight of the dielectric film forming composition.

In some embodiments, the dielectric film forming composition of this disclosure further includes one or more (e.g., two, three, or four) adhesion promoter. Suitable adhesion promoters are described in “Silane Coupling Agent” Edwin P. Plueddemann, 1982 Plenum Press, New York.

Examples of suitable adhesion promoters which can be employed in the compositions of this disclosure can be described by Structure (XIV):

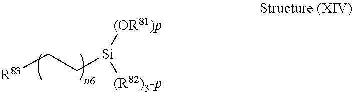

in which each R⁸¹ and R⁸² independently is a substituted or unsubstituted C₁-C₁₀ linear or branched alkyl group or a substituted or unsubstituted C₃-C₁₀ cycloalkyl group, p is an integer from 1 to 3, n6 is an integer from 1 to 6, R⁸³ is one of the following moieties:

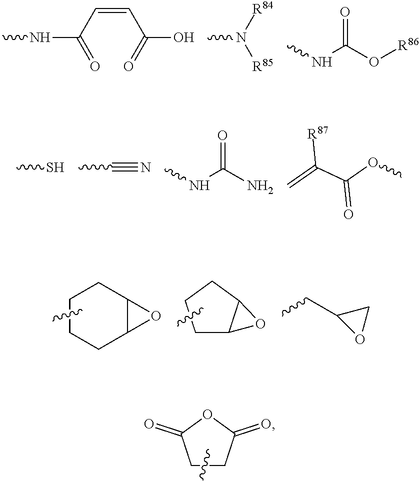

in which each of R⁸⁴, R⁸⁵, R⁸⁶ and R⁸⁷, independently, is a C₁-C₄ alkyl group or a C₅-C₇ cycloalkyl group. Preferred adhesion promoters are those (including methacrylate/acrylate) in which R⁸³ is selected from:

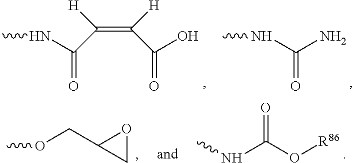

In some embodiments, the amount of the optional adhesion promoter is at least about 0.5 weight % (e.g., at least about 0.8 weight %, at least about 1 weight %, or at least about 1.5 weight %) and/or at most about 4 weight % (e.g., at most about 3.5 weight %, at most about 3 weight %, at most about 2.5 weight %, or at most about 2 weight %) of the total weight of the dielectric film forming composition.

The dielectric film forming composition of this disclosure can also optionally contain one or more (e.g., two, three, or four) surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988.

In some embodiments, the amount of the surfactant is at least about 0.005 weight % (e.g., at least about 0.01 weight % or at least about 0.1 weight %) and/or at most about 1 weight % (e.g., at most about 0.5 weight % or at most about 0.2 weight %) of the total weight of the dielectric film forming composition.

The dielectric film forming composition of the present disclosure can optionally contain one or more (e.g., two, three, or four) plasticizers.

The dielectric film forming composition of the present disclosure can optionally contain one or more (e.g., two, three, or four) corrosion inhibitor. Examples of corrosion inhibitors include triazole compounds, imidazole compounds and tetrazole compounds. Triazole compounds can include triazoles, benzotriazoles, substituted triazoles, and substituted benzotriazoles. Examples of triazole compounds include, but are not limited to, 1,2,4-triazole, 1,2,3-triazole, or triazoles substituted with substituents such as C₁-C₈ alkyl (e.g., 5-methyltriazole), amino, thiol, mercapto, imino, carboxy and nitro groups. Specific examples include benzotriazole, tolyltriazole, 5-methyl-1,2,4-triazole, 5-phenyl-benzotriazole, 5-nitro-benzotriazole, 3-amino-5-mercapto-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, and the like. Examples of imidazole include, but are not limited to, 2-alkyl-4-methyl imidazole, 2-phenyl-4-alkyl imidazole, 2-methyl-4(5)-nitroimidazole, 5-methyl-4-nitroimidazole, 4-Im idazolemethanol hydrochloride, and 2-mercapto-1-methylimidazole. Examples of tetrazole include 1H-tetrazole, 5-methyl-1H-tetrazole, 5-phenyl-1H-tetrazole, 5-amino-1H-tetrazole,1-phenyl-5-mercapto-1H-tetrazole, 5,5′-bis-1H-tetrazole, 1-methyl-5-ethyltetrazole, 1-methyl-5-mercaptotetrazole, 1-carboxym ethyl-5-mercaptotetrazole, and the like. The amount of the optional corrosion inhibitor, if employed, is at least about 0.1 weight % (e.g., at least about 0.2 weight % or at least about 0.5 weight %) and/or at most about 3.0 weight % (e.g., at most about 2.0 weight % or at most about 1.0 weight %) of the entire weight of the dielectric film forming composition of this disclosure.

In some embodiments, the dielectric film forming composition of this disclosure can optionally contain one or more (e.g., two, three, or four) dyes and/or one or more colorants.

In some embodiments, a photosensitive polyimide film is prepared from a dielectric film forming composition of this disclosure by a process containing the steps of:

a) coating a substrate with the dielectric film forming composition described herein to form a coated substrate having a photosensitive dielectric film; and

b) optionally baking the coated substrate (e.g., at a temperature from about 50° C. to about 150° C. for about 20 seconds to about 600 seconds) to for a dried film.

In general, the coating can be performed by a fluid coating method. Fluid coating is a general term that refers to applying a fluid to a substrate. In a fluid coating operation, the fluid can be at room temperature or heated. The fluid coating can be achieved by using several techniques such as 1) liquid coating, 2) hot melt coating, and 3) extrusion coating. In liquid coating, the solution flows at room temperature, whereas fluid directly feed from the extruder to the coating head in the extrusion coating. In the hot melt coating, the composition feeds from an adhesive melter by a precision metering pump to a coating head. Extrusion coating and hot melt coating utilizes cooling to develop a solid film coating, whereas the liquid coating requires heating sources to solidify the liquid on the substrate.

Coating methods for preparation of the photosensitive polyimide film include, but are not limited to, (1) spin coating, (2) spray coating, (3) roll coating, (4) rod coating, (5) rotation coating, (6) slit coating, (7) compression coating, (8) curtain coating, (9) slot die coating, (10) wire bar coating, (11) knife coating and (12) lamination of dry film. The slot die coating process can be used for 1) liquid coating, 2) hot melt coating, and 3) extrusion coating. The slot die coating process can be used for these types of coating by adjusting geometry of slot die lip faces and the gap between die and the coating substrates. One skilled in the art would choose the appropriate coating method based on the coating type such as liquid coating, hot melt coating or extrusion coating.

Substrates that can be coated by a composition described herein can have circular, square or rectangular shapes such as wafers or panels in various dimensions. Examples of suitable substrates include epoxy molded compound (EMC), silicon, glass, copper, stainless steel, copper cladded laminate (CCL), aluminum, silicon oxide, silicon nitride, or a combination thereof. Substrates can also be made from a flexible material (e.g., an organic film) such as a polyimide, PEEK, polycarbonate, PES (polyether sulfone), polystyrene, or polyester film, which can include organic fibers or inorganic filler such as silica, alumina, titania, zirconia, hafnium oxide, CdSe, CdS, CdTe, CuO, zinc oxide, lanthanum oxide, niobium oxide, tungsten oxide and the like. In some embodiments, substrates can have surface mounted or embedded chips, dyes, or packages. In some embodiments, substrates can be sputtered or pre-coated with a combination of seed layer and passivation layer.

Film thickness of the dielectric film (e.g., photosensitive polyimide film) of this disclosure is not particularly limited. In some embodiments, the dielectric film (e.g., photosensitive polyimide film) has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns, at most about 60 microns, at most about 50 microns, at most about 40 microns, or at most about 30 microns). In some embodiments, the film thickness of the photosensitive polyimide film is less than about 5 microns (e.g., less than about 4.5 microns, less than about 4.0 microns, less than about 3.5 microns, less than about 3.0 microns, less than about 2.5 microns, or less than about 2.0 microns).

The viscoelasticity properties of uncured dielectric film (e.g., photosensitive polyimide film) can be measured by dynamic mechanical analysis (DMA). In some embodiments, the uncured dielectric film prepared by using the composition described herein has a Tan delta Tg (as determined by DMA) in the range of from about 55° C. to about 90° C. (e.g., from about 60° C. to about 85° C., or from about 65° C. to about 80° C.). Without wishing to be bound by theory, it is believed that higher tan delta Tg is better for film integrity in a roll form where a covering layer is used to protect film from environmental contaminations as a higher temperature is required during lamination of a dry film to a substrate.

In some embodiments, the process to prepare a patterned dielectric film (e.g., polyimide film) includes converting the photosensitive dielectric film (e.g., a dried photosensitive polyimide film on a coated substrate) into a patterned polyimide film by a lithographic process. In such cases, the conversion can include exposing the dielectric film (e.g., photosensitive polyimide film) to high energy radiation (such as those described above) using a patterned mask such that the exposed portions of the film are cross-linked, thereby forming a dried, patternwise exposed film. After the dielectric film (e.g., polyimide film) is exposed to high energy radiation, the process can further include developing the exposed dielectric film to remove the unexposed portions to form a patterned dielectric film.

After the exposure, the dielectric film (e.g. polyimide film) can be heat treated to at least about 50° C. (e.g., at least about 55° C., at least about 60° C., or at least about 65° C.) to at most about 150° C. (e.g., at most about 135° C., or at most about 120° C., at most about 105° C., at most about 90° C., at most about 80° C., or at most about 70° C.) for at least about 60 seconds (e.g., at least about 65 seconds, or at least about 70 seconds) to at most about 240 seconds (e.g., at most about 180 seconds, at most about 120 seconds, or at most about 90 seconds) in a second baking step. The heat treatment is usually accomplished by use of a hot plate or oven.

After the exposure and heat treatment, the dielectric film (e.g., polyimide film) can be developed to remove unexposed portions by using a developer to form a relief image on the substrate. Development can be carried out by, for example, an immersion method or a spraying method. Microholes and fine lines can be generated in the polyimide film on the substrate after development.

In some embodiments, the polyimide film can be developed by use of an organic developer. Examples of such developers can include, but are not limited to, gamma-butyrolactone (GBL), dimethyl sulfoxide (DMSO), N,N-diethylacetamide, methyl ethyl ketone (MEK), methyl isobutyl ketone (MIBK), 2-heptanone, cyclopentanone (CP), cyclohexanone, n-butyl acetate (nBA), propylene glycol methyl ether acetate (PGMEA), propylene glycol methyl ether (PGME), ethyl lactate (EL), propyl lactate, 3-methyl-3-methoxybutanol, tetralin, isophorone, ethylene glycol monobutyl ether, diethylene glycol monoethyl ether, diethylene glycol monoethyl ether acetate, diethylene glycol dimethyl ether, diethylene glycol methylethyl ether, triethylene glycol monoethyl ether, dipropylene glycol monomethyl ether, methyl 3-methoxypropionate, ethyl 3-ethoxypropionate, diethyl malonate, ethylene glycol, 1,4:3,6-dianhydrosorbitol, isosorbide dimethyl ether, 1,4:3,6-dianhydrosorbitol 2,5-diethyl ether (2,5-diethylisosorbide) and mixtures thereof. Preferred developers are gamma-butyrolactone (GBL), cyclopentanone (CP), cyclohexanone, ethyl lactate (EL), n-butyl acetate (nBA) and dimethylsulfoxide (DMSO). More preferred developers are gamma-butyrolactone (GBL), cyclopentanone (CP) and cyclohexanone. These developers can be used individually or in combination of two or more to optimize the image quality for the particular composition and lithographic process.

In some embodiments, the dielectric film (e.g., polyimide film) can be developed by using an aqueous developer. When the developer is an aqueous solution, it preferably contains one or more aqueous bases. Examples of suitable bases include, but are not limited to, inorganic alkalis (e.g., potassium hydroxide or sodium hydroxide), primary amines (e.g., ethylamine or n-propylamine), secondary amines (e.g. diethylamine or di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed can vary depending on, e.g., the base solubility of the polymer employed. The most preferred aqueous developers are those containing tetramethylammonium hydroxide (TMAH). Suitable concentrations of TMAH range from about 1% to about 5% of the aqueous developer.

In some embodiments, after the development by an organic developer, an optional rinse treatment of the relief image formed above can be carried out with an organic rinse solvent. One skilled in the art will know which rinse method is appropriate for a given application. Suitable examples of organic rinse solvents include, but are not limited to, alcohols such as isopropyl alcohol, methyl isobutyl carbinol (MIBC), propylene glycol monomethyl ether (PGME), amyl alcohol, esters such as n-butyl acetate (nBA), ethyl lactate (EL) and propylene glycol monomethyl ether acetate (PGMEA), ketones such as methyl ethyl ketone, and mixtures thereof. A rinse solvent can be used to carry out the rinse treatment to remove residues.

In some embodiments, after the development step or the optional rinse treatment step, an optional third baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining polyimide film and can further crosslink the remaining polyimide film. Post development bake can be done in air or preferably under a blanket of nitrogen and can be carried out by any suitable heating means.

In some embodiments, the patterned dielectric film includes at least one element having a feature size (e.g., height, length, or width) of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 microns).

In some embodiments, the aspect ratio (i.e., the ratio of height to width) of the smallest feature of a patterned dielectric film after completion of the above lithographic process is at least about 1/1 (e.g. at least about 1.5/1, at least about 2/1, at least about 2.5/1, or at least about 3/1).

In some embodiments, the process to prepare a patterned dielectric film can include converting the dielectric film (e.g., photosensitive polyimide film) into a patterned dielectric film by a laser ablation technique. Direct laser ablation process with an excimer laser beam is generally a dry, one step material removal to form openings (or patterns) in the dielectric film (e.g., polyimide film). In some embodiments, the wavelength of the laser is 351 nm or less (e.g., 351 nm, 308 nm, 248 nm, or 193 nm). Examples of suitable laser ablation processes include, but are not limited to, the processes described in U.S. Pat. Nos. 7,598,167, 6,667,551, and 6,114,240, the contents of which are hereby incorporated by reference. One important aspect of this disclosure is that the dielectric films (e.g., polyimide films) prepared from the dielectric film-forming composition described herein are capable of producing a patterned film with a feature size of at most about 3 microns (e.g., at most 2 microns or at most 1 micron) by a laser ablation process.

In some embodiments, the patterned dielectric film (e.g., polyimide film) has a dielectric constant of from at least about 2.8 (e.g., at least about 2.9, at least about 3, or at least about 3.1) to at most about 3.5 (e.g., at most about 3.4, at most about 3.3, or at most about 3.2) measured at 20 GHz.

In some embodiments, this disclosure features a process for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. For example, the process can include the steps of: (a) depositing a dielectric film-forming composition of this disclosure on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; d) optionally depositing a seed layer on the patterned dielectric film; and (e) depositing a metal layer (e.g., an electrically conductive metal layer) in at least one opening in the patterned dielectric film to form a metal pattern. In some embodiments, steps (a)-(e) can be repeated one or more (e.g., two, three, or four) times.

In some embodiments, this disclosure features a process to deposit a metal layer (e.g., an electrically conductive copper layer to create an embedded copper trace structure) on a semiconductor substrate. In some embodiment, to achieve this, a seed layer conformal to the patterned dielectric film is first deposited on the patterned dielectric film (e.g., outside the openings in the film). Seed layer can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-aspect-ratio) features. The fill factor by sputtering deposition has been improved by collimating the sputtered flux. Typically, this is achieved by inserting between the target and substrate a collimator plate having an array of hexagonal cells.

Next step in the process is metal seeding deposition. A thin metal (e.g., an electrically conductive metal such as copper) seeding layer can be formed on top of the barrier layer in order to improve the deposition of the metal layer (e.g., a copper layer) formed in the succeeding step.

Next step in the process is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. Pat. No. 5,891,804 (Havemann et al.), U.S. Pat. No. 6,399,486 (Tsai et al.), and U.S. Pat. No. 7,303,992 (Paneccasio et al.), the contents of which are hereby incorporated by reference.

In some embodiments, the process of depositing an electrically conductive metal layer further includes removing overburden of the electrically conductive metal or removing the seed layer (e.g., the barrier layer and the metal seeding layer). In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5248,398, and US Application Publication No. 2017175274, the contents of which are hereby incorporated by reference.

Some embodiments describe a process for surrounding a metal structured substrate containing conducting metal (e.g., copper) wire structures forming a network of lines and interconnects with the dielectric film of this disclosure. The process can include the steps of:

a) providing a substrate containing conducting metal wire structures that form a network of lines and interconnects on the substrate;

b) depositing a dielectric film-forming composition of this disclosure on the substrate to form a dielectric film (e.g., that surrounds the conducting metal lines and interconnects; and

c) exposing the dielectric film to a source of radiation or heat or a combination of radiation and heat (with or without a mask) to form a surrounding metal pattern (i.e., a metal pattern surrounded by a dielectric film).

The above steps can be repeated multiple times (e.g., two, three, or four times) to form a complex multi-layered three-dimensional object.

In general, the processes described above can be used to form an article to be used in a semiconductor device. Examples of such articles include a semiconductor substrate, a flexible film for electronics, a wire isolation, a wire coating, a wire enamel, or an inked substrate. Examples of semiconductor devices that can be made from such articles include an integrated circuit, a light emitting diode, a solar cell, and a transistor.

In some embodiments, this disclosure features a three dimensional object containing at least one patterned film formed by a process described herein. In some embodiments, the three dimensional object can include patterned films in at least two stacks (e.g., at least three stacks).

In some embodiments, this disclosure features a method of preparing a dry film structure. The method includes: (A) coating a carrier substrate (e.g., a substrate including at least one plastic film) with a dielectric film forming composition described herein to form a coated composition; (B) drying the coated composition to form a photosensitive polyimide film; and (C) optionally applying a protective layer to the photosensitive polyimide film to form a dry film structure. In some embodiments, the method can further include applying the dry film structure onto an electronic substrate to form a laminate, in which the photosensitive polyimide layer in the laminate is between the electronic substrate and the carrier substrate.

In some embodiments, the carrier substrate is a single or multiple layer plastic film, which can include one or more polymers (e.g., polyethylene terephthalate). In some embodiments, the carrier substrate has excellent optical transparency and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer substrate is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

In some embodiments, the photosensitive polyimide film of the dry film can be delaminated from carrier layer as a self-standing photosensitive polyimide film. A self-standing photosensitive polyimide film is a film that can maintain its physical integrity without using any support layer such as a carrier layer. In some embodiments, the self-standing photosensitive polyimide film can include a) a plurality of (meth)acrylate containing compounds described herein, and b) at least one fully imidized polyimide polymer; and is substantially free of any solvent.

In some embodiments, the photosensitive polyimide film of the dry film structure can be laminated to a substrate (e.g., a semiconductor or an electronic substrate) using a vacuum laminator at about 50° C. to about 140° C. after pre-laminating of the photosensitive polyimide film of the dry film structure with a plane compression method or a hot roll compression method. When the hot roll compression is employed, the dry film structure can be placed into a hot roll laminator, the optional protective layer can be peeled away from the photosensitive polyimide film/carrier substrate, and the photosensitive polyimide film can be brought into contact with and laminated to a substrate using rollers with heat and pressure to form an article containing the substrate, the photosensitive polyimide film, and the carrier substrate. The polyimide film can then be exposed to a source of radiation or heat (e.g., through the carrier substrate) to form a crosslinked photosensitive polyimide film. In some embodiments, the carrier substrate can be removed before exposing the photosensitive polyimide film to a source of radiation or heat.

Some embodiments of this disclosure describe a process of generating a photosensitive polyimide film (e.g., a planarizing photosensitive polyimide film) on a substrate with a copper pattern. In some embodiments, the process includes depositing a dielectric film forming composition described herein onto a substrate with a copper pattern to form a dielectric film. In some embodiments, the process includes steps of:

a. providing a dielectric film forming composition of this disclosure, and

b. depositing the dielectric film forming composition onto a substrate with a copper pattern to form a dielectric film, wherein the difference in the highest and lowest points on a surface (e.g., a top surface) of the dielectric film is at most about 2 microns (e.g., at most about 1.5 microns, at most about 1 micron, or at most about 0.5 micron).

The present disclosure is illustrated in more detail with reference to the following examples, which are for illustrative purposes and should not be construed as limiting the scope of the present disclosure.

### EXAMPLES

### Composition Example 1

A dielectric film forming composition FE-1 was prepared by using 100 parts of a 32.46% solution of a polyimide polymer (P-1) having the structure shown below and a weight average molecular weight of 54,000 in cyclopentanone, 30.1 parts of cyclopentanone, 8.9 parts of GBL,1.9 parts of a 0.5 wt % solution of PolyFox 6320 (available from OMNOVA Solutions) in GBL, 1.6 parts of methacryloxypropyltrimethoxy silane, 1.0 part of 2-(O-benzoyloxime)-1-[4-(phenylthio)phenyl]-1,2-octanedione (Irgacure OXE-1 from BASF), 0.03 parts of t-butylcatechol, 10.5 parts of tetraethylene glycol diacrylate, 4.1 parts of pentaerythritol triacrylate, 1.6 parts of ethylene glycol dicyclopentenyl ether acrylate and 0.2 parts of 5-methyl benzotriazole. After being stirred mechanically for 24 hours, the solution was filtered by using a 0.2 micron filter (Ultradyne from Meissner Corporation, cat # CLTM0.2-552).

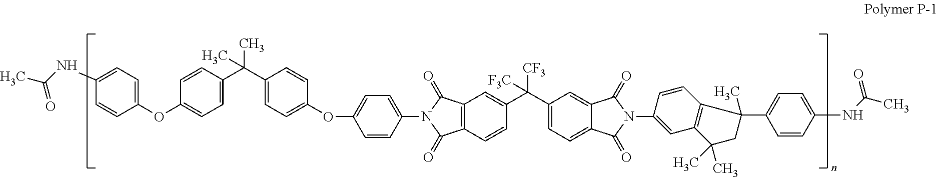

### Reliability Test Example 1

The dielectric film forming composition of Example 1 was spin-coated at 1200 rpm onto a silicon oxide wafer with copper-plated line/space pattern ranging from 8/8 microns to 15/15 microns at 6 micron thickness, and baked at 95° C. for 5 minutes using a hot plate to form a coating with a thickness of about 13 microns. The dielectric film forming composition was then blanket exposed at 500 mJ/cm² by using an LED i-line exposure tool. The composition was cured at 170° C. for 2 hours in a YES oven. After cure, the wafer was cleaved into individual chips.

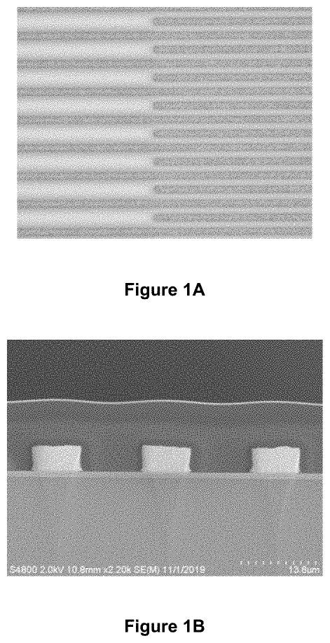

Three chips were heated in an ESPEC reliability test chamber at 130° C., 85% RH for unbiased Highly Accelerated Stress Test (uHAST) for 96, 168 and 210 hours. No cracking or delamination was observed by optical microscope at 96, 168, and 210 hours (FIG. 1A), or by cross-sectional SEM after cleaving and ion milling samples at 96, 168, and 210 hours (FIG. 1B).

### Comparative Composition Example 1

A comparative dielectric film forming composition CFE-1 was prepared by using 100 parts of a 32.46% solution of a polyimide polymer (P-1) having the structure shown above and a weight average molecular weight of 54,000 in cyclopentanone, 30.1 parts of cyclopentanone, 8.9 parts of GBL,1.9 parts of a 0.5 wt % solution of PolyFox 6320 (available from OMNOVA Solutions) in GBL, 1.6 parts of gamma-glycidoxypropyltrimethoxysilane, 0.98 parts of 2-(O-benzoyloxime)-1-[4-(phenylthio)phenyl]-1,2-octanedione (Irgacure OXE-1 from BASF), 0.03 parts of t-butylcatechol, 12.1 parts of tetraethylene glycol diacrylate, 4.0 parts of pentaerythritol triacrylate, and 0.16 parts of 5-methyl benzotriazole. In other words, composition CFE-1 differed from composition FE-1 in that CFE-1 did not include a monoacrylate containing compound. After being stirred mechanically for 24 hours, the solution was filtered by using a 0.2 micron filter (Ultradyne from Meissner Corporation, cat # CLTM0.2-552).

### Reliability Test Comparative Example 1

The dielectric film forming composition of Comparative Example 1 was spin-coated at 1200 rpm onto a silicon oxide wafer with copper-plated line/space pattern ranging from 8/8 microns to 15/15 microns at 6 micron thickness, and baked at 95° C. for 5 minutes using a hot plate to form a coating with a thickness of about 13 microns. The dielectric composition was then blanket exposed at 500 mJ/cm² by using an LED i-line exposure tool. The composition was cured at 170° C. for 2 hours in a YES oven. After cure, the wafer was cleaved into individual chips.

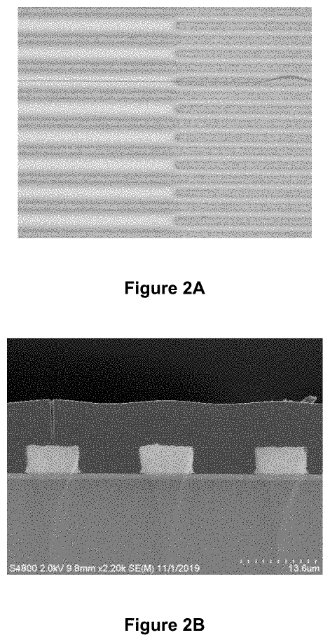

Three chips were heated in an ESPEC reliability test chamber at 130° C., 85% RH for unbiased Highly Accelerated Stress Test (uHAST) for 96, 168 and 210 hours. No cracking or delamination was observed by optical microscope at 96 hours. Some cracking was observed at 168 hours and more cracking and some delamination was observed at 210 hours (FIG. 2A). Cracking was observed by cross-sectional SEM after cleaving and ion milling samples at 210 hours (FIG. 2B).

### Dry Film Example 1

A dielectric film forming composition FE-2 was prepared by using 1345.24 g of a 31.69% solution of a polyimide polymer (P-1) having the structure shown in Composition Example 1 and a weight average molecular weight of 58200 in cyclopentanone, 1021.91 g of propylene carbonate, 102.31 g of a 0.5 wt % solution of PolyFox 6320 (available from OMNOVA Solutions) in propylene carbonate, 21.31 g of methacryloxypropyltrimethoxy silane, 12.79 g of 2-(O-benzoyloxime)-1-[4-(phenylthio)phenyl]-1,2-octanedione (Irgacure OXE-1 from BASF), 0.43 g of monomethyl ether hydroquinone, 138.55 g of tetraethylene glycol diacrylate, 53.39 g of pentaerythritol triacrylate, 21.32 g of ethylene glycol dicyclopentenyl ether acrylate, 4.26 g of dicumyl peroxide and 0.426 g of 5-methyl benzotriazole. After being stirred mechanically for 24 hours, the solution was filtered by using a 0.2 micron filter. Tan delta Tg of dielectric film forming composition FE-2 was 73° C. (as determined by dynamic mechanical analysis: DMA)

This dielectric film forming composition FE-2 was applied using slot die coater from Fujifilm USA (Greenwood, S.C.) with line speed of 2 feet/minutes (61 cm per minutes) with 60 microns clearance onto a polyethylene terephthalate (PET) film (TCH21, manufactured by DuPont Teijin Films USA) having a width of 16.2″ and thickness of 36 microns used as a carrier substrate and dried at 194° F. to obtain a photosensitive polymeric layer with a thickness of approximately 30.3 microns (DF-1). On this polymeric layer, a biaxially oriented polypropylene film having width of 16″ and thickness of 30 microns (BOPP, manufactured by Impex Global, Houston, Tex.) was laid over by a roll compression to act as a protective layer.

### Dry Film Example 2

A dielectric film forming composition FE-3 was prepared by using 2685.63 g of a 30.02% solution of a polyimide polymer (P-1) having the structure shown in Composition Example 1 and a weight average molecular weight of 61000 in cyclopentanone, 13.51 g of cyclopentanone, 1777.65 g of propylene carbonate,193.49 g of a 0.5 wt % solution of PolyFox 6320 (available from OMNOVA Solutions) in propylene carbonate, 40.31 g of methacryloxypropyltrimethoxy silane, 24.19 g of 2-(0-benzoyloxime)-1-[4-(phenylthio)phenyl]-1,2-octanedione (Irgacure OXE-1 from BASF), 1.61 g of monomethyl ether hydroquinone, 262.02 g of tetraethylene glycol diacrylate, 100.78 g of pentaerythritol triacrylate, 40.31 of ethylene glycol dicyclopentenyl ether acrylate, 8.06 g of dicumyl peroxide and 1.61 g of 5-methyl benzotriazole. After being stirred mechanically for 24 hours, the solution was filtered by using a 0.2 micron filter.

This dielectricfilm forming composition FE-3 was applied using slot die coater from Fujifilm USA (Greenwood, S.C.) with line speed of 2 feet/minutes (61 cm per minutes) with 60 microns clearance onto a polyethylene terephthalate (PET) film (TCH21, manufactured by DuPont Teijin Films USA) having a width of 16.2″ and thickness of 36 microns used as a carrier substrate and dried at 194° F. to obtain a photosensitive polymeric layer with a thickness of approximately 6.5 microns (DF-2). On this polymeric layer, a biaxially oriented polypropylene film having width of 16″ and thickness of 30 microns (BOPP, manufactured by Impex Global, Houston, Tex.) was laid over by a roll compression to act as a protective layer.

### Example of Formation of Polyimide Dielectric Film with Planarized Surface

This example demonstrates lithographically patterning photosensitive dielectric film on a planarized surface.

A dielectric film forming composition FE-4 was prepared by using 89.19 g of a 30.02% solution of a polyimide polymer (P-1) having a weight average molecular weight of 58200 in cyclopentanone, 38.08 g of propylene carbonate, 1.61 g of a 0.5 wt % solution of PolyFox 6320 (available from OMNOVA Solutions) in propylene carbonate, 1.34 g of methacryloxypropyltrimethoxy silane, 0.80 g of 2-(O-benzoyloxime)-1-[4-(phenylthio)phenyl]-1,2-octanedione (Irgacure OXE-1 from BASF), 0.054 g of monomethyl ether hydroquinone, 8.70 g of tetraethylene glycol diacrylate, 3.35 g of pentaerythritol triacrylate, 1.34 g of ethylene glycol dicyclopentenyl ether acrylate, 0.268 g of dicumyl peroxide and 0.134 g of 5-methyl benzotriazole. After being stirred mechanically for 24 hours, the solution was filtered by using a 0.2 micron filter.

The test substrate was prepared by using a 4 inch silicon wafer with copper peaks with 100-micron space between them. The thickness of copper peaks was 3.5 microns. The dielectric film forming composition was deposited by spin coating on the test substrate to form a photosensitive polyimide film, which was soft-baked at 90° C. for 3 minutes, exposed through a mask using an i-line stepper (Cannon i4), developed in cyclopentanone (2×70 seconds), rinsed with propylene glycol monomethyl ether acetate (PGMEA), and cured at 170° C. for 2 hours in an oven with nitrogen atmosphere.

The difference between the highest and lowest points on a top surface of the polyimide based dielectric film was measured at three stages as follows

TABLE 1
Difference in the highest and lowest points on
top surface of the polyimide based dielectric film

| After | After | After |
|---|---|---|
| softbake | development | curing |
| (μm) | (μm) | (μm) |
| 1.3 | 0.9 | 0.6 |

### Comparative Example of Formation of Polyimide Dielectric Film with Planarized Surface

A dielectric film forming composition CFE-2 is prepared by using 89.19 g of a 30.02% solution of a polyimide polymer (P-1) having a weight average molecular weight of 58200 in cyclopentanone, 27.38 g of cyclopentanone, 10.70 g of GBL,1.61 g of a 0.5 wt % solution of PolyFox 6320 (available from OMNOVA Solutions) in cyclopentanone, 1.34 g of methacryloxypropyltrimethoxy silane, 0.80 g of 2-(O-benzoyloxime)-1-[4-(phenylthio)phenyl]-1,2-octanedione (Irgacure OXE-1 from BASF), 0.054 g of monomethyl ether hydroquinone, 8.70 g of tetraethylene glycol diacrylate, 3.35 g of pentaerythritol triacrylate, 1.34 g of ethylene glycol dicyclopentenyl ether acrylate, 0.268 g of dicumyl peroxide and 0.134 g of 5-methyl benzotriazole. In other words, Composition CFE-2 is similar to composition FE-4 except that FE-4 includes propylene carbonate as a solvent, while CFE-2 includes cyclopentanone and GBL as solvents.

The test substrate is prepared by using a 4 inch silicon wafer with copper peaks with 100-micron space between them. The thickness of copper peaks is 3.5 microns. The dielectric film forming composition is deposited by spin coating on the test substrate to form a photosensitive polyimide film, which is soft-baked at 90° C. for 3 minutes, exposed through a mask using an i-line stepper (Cannon i4), developed in cyclopentanone (2×70 seconds), rinsed with propylene glycol monomethyl ether acetate (PGMEA), and cured at 170° C. for 2 hours in an oven with nitrogen atmosphere to form a polyimide based dielectric film.

The difference between the highest and lowest points on a top surface of the polyimide based dielectric film is measured after softbake, after development, and after curing.

### Example of Formation of Three-Dimensional Object

The dielectric film-forming composition of Example FE-2 is spin-coated at 1200 rpm onto a silicon oxide wafer with copper-plated line/space/height pattern ranging from 8/8/6 microns to 15/15/6 microns. The coated film is baked at 95° C. for 5 minutes using a hot plate to form a film having a thickness of about 13 microns. The photosensitive composition is then exposed at 500 mJ/cm² by using a 355 nm UV laser to create patterns in the form of contact holes on top of underline metal pad. The photosensitive composition is cured at 170° C. for 2 hours in a YES oven. Copper metal is then deposited into the contact holes by electrodeposition process.

Electrodeposition of copper is achieved using an electrolyte composition containing copper ion (30 g/L), sulfuric acid (50 g/L), chloride ion (40 ppm), poly(propylene glycol) (500 ppm), disodium 3,3-dithiobis(1-propanesulfonate (200 ppm) and bis(sodium sulfopropyl) disulfide (100 μm). Electroplating is performed in a beaker while stirring using the following conditions: Anode: Copper; Plating temperature: 25° C.; Current density: 10 mA/cm²; and Time: 2 minutes. After electroplating, the fine trenches are cut and the copper filling conditions are inspected using optical and scanning electron microscopes to confirm that the copper is completely filled without any voids. Also the time of deposition is controlled to avoid formation of overburden. Thus, a three-dimensional object where individual copper structures are surrounded by the dielectric film is prepared.

### Example of Copper Deposition

The dielectric film-forming composition of Example FE-2 is spin-coated at 1200 rpm onto a PVD-copper wafer. This film is then baked at 95° C. for 6 mins using a hot plate to produce a photosensitive composition film with a thickness of 8 microns. The photosensitive composition film is exposed with a Canon i-line stepper (NA 0.45, SIGMA 0.7) through a trench test pattern reticle at a fixed dose of 500 mJ/cm² and −1 micron fixed focus. The exposed photosensitive layer is then developed by using dynamic development of cyclopentanone for 40 seconds to resolve trenches of dimensions of 50 microns and below including ultrafine 4 microns trench pattern as observed by an optical microscope (and confirmed by cross-section scanning electron microscope (SEM). The photosensitive composition is cured at 170° C. for 2 hours in a YES oven. The wafer is then electroplated as described in Example of Formation of Three-Dimensional Object above and 3.0 microns high copper lines are produced in all trenches as observed by SEM.

1. A dielectric film forming composition, comprising:
a plurality of (meth)acrylate containing compounds, wherein the plurality of (meth)acrylate containing compounds comprise:
at least one mono(meth)acrylate containing compound of structure (I), 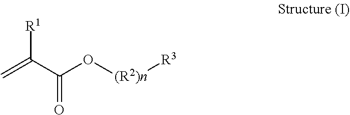
wherein R¹ is a hydrogen atom, a C₁-C₃ alkyl group, a fully or partially halogen substituted C₁-C₃ alkyl group, or a halogen atom; R² is a C₂-C₁₀ alkylene group, a C₅-C₂₀ cycloalkylene group, or a R⁴O group, wherein R⁴ is a linear or branched C₂-C₁₀ alkylene group or a C₅-C₂₀ cycloalkylene group; R³ is a substituted or unsubstituted linear, branched or cyclic C₁-C₁₀ alkyl group, a saturated or unsaturated C₅-C₂₅ alicyclic group, a C₆-C₁₈ aryl group, or a C₇-C₁₈ alkylaryl group; and n is 0 or 1;
at least one di(meth)acrylate containing cross linker; and
optionally at least one multi(meth)acrylate containing cross linker comprising at least 3 (meth)acrylate groups;
at least one fully imidized polyimide polymer; and
optionally, at least one solvent.

2. The composition of claim 1, wherein the at least one mono(meth)acrylate containing compound is selected from the group consisting of isobornyl acrylate, isobornyl methacrylate, dicyclopentenyloxyethyl acrylate, dicyclopentenyl acrylate, dicyclopentenyloxyethyl methacrylate, dicyclopentenyl methacrylate, bicyclo[2.2.2]oct-5-en-2-yl acrylate, bicyclo[2.2.2]oct-5-en-2-yl methacrylate, 2-[(bicyclo[2.2.2]oct-5-en-2-yl)oxy]ethyl acrylate, 2-[(bicyclo[2.2.2]oct-5-en-2-yl)oxy]ethyl methacrylate, 3a,4,5,6,7,7a-hexahydro-1H-4,7-ethanoinden-6-yl acrylate, 3a,4,5,6,7,7a-hexahydro-1H-4,7-ethanoinden-6-yl methacrylate, 2-[(3a,4,5,6,7,7a-hexahydro-1H-4,7-ethanoinden-6-yl)oxy]ethyl acrylate, 2-[(3a,4,5,6,7,7a-hexahydro-1H-4,7-ethanoinden-6-yl)oxy]ethyl methacrylate, tricyclo[5,2,1,0^{2,6}]decyl acrylate, tricyclo[5,2,1,0^{2,6}]decyl methacrylate, tetracyclo[4,4,0,1^{2,5},1^{7,10}]dodecanyl acrylate, and tetracyclo[4,4,0,1^{2,5},1^{7,10}]dodecanyl methacrylate.

3. The composition of claim 1, wherein the at least one mono(meth)acrylate containing compound is

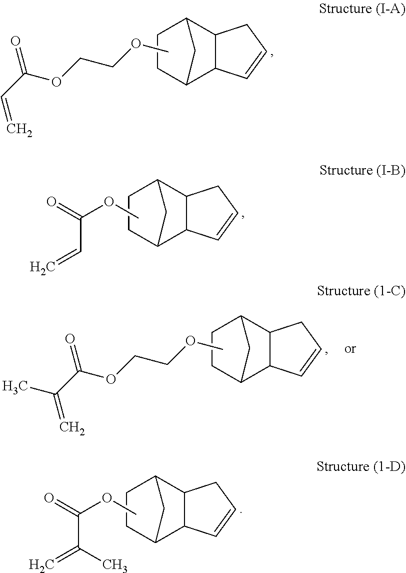

4. The composition of claim 1, wherein the at least one mono(meth)acrylate containing compound is in an amount of from about 1% to about 50% by weight of the plurality of (meth)acrylate containing compounds.

5. The composition of claim 1, wherein the at least one di(meth)acrylate containing cross linker is in an amount of from about 20% to about 85% by weight of the plurality of (meth)acrylate containing compounds.

6. The composition of claim 1, wherein the at least one multi(meth)acrylate containing cross linker is in an amount of from 0% to about 40% by weight of the plurality of (meth)acrylate containing compounds.

7. The composition of claim 1 wherein the amount of at least one mono(meth)acrylate containing compound in the composition is from 0.1 to 10% of the total amount of the dielectric film forming composition.

8. The composition of claim 1, further comprising at least one photoinitiator.

9. A patterned dielectric film produced by the composition of claim 1.

10. The patterned dielectric film of claim 9, wherein the patterned dielectric film is produced by:
a) depositing the dielectric film forming composition of claim 1 on a substrate to form a dielectric film;
b) patterning the dielectric film by a lithographic method or by a laser ablation method.

11. A three dimensional object, comprising at least one patterned dielectric film of claim 9 and at least one substrate.

12. The three dimensional object of claim 11, wherein the substrate comprises an organic film, an epoxy molded compound (EMC), silicon, glass, copper, stainless steel, copper cladded laminate (CCL), aluminum, silicon oxide, silicon nitride, or a combination thereof.

13. The three dimensional object of claim 11, wherein the substrate comprises a metal pattern.

14. A process for preparing the three dimensional object of claim 13, comprising:
a) depositing the dielectric film forming composition on a substrate to form a dielectric film;
b) exposing the dielectric film to radiation or heat or a combination of radiation or heat;
c) patterning the dielectric film to form a patterned dielectric film having openings;
d) optionally depositing a seed layer on the patterned dielectric film; and
e) depositing a metal layer in at least one opening in the patterned dielectric film to form a metal pattern.

15. The three dimensional object of claim 11, wherein the patterned dielectric film comprises surrounding copper patterns.

16. A process for forming the three dimensional object of claim 15, comprising:
a) providing a substrate containing copper conducting metal wire structures that form a network of lines and interconnects on the substrate;
b) depositing the dielectric film forming composition on the substrate to form a dielectric film; and
c) exposing the dielectric film to radiation or heat or a combination of radiation and heat.

17. A semiconductor device, comprising the three dimensional object of claim 11.

18. The semiconductor device of claim 17, wherein the semiconductor device is an integrated circuit, a light emitting diode, a solar cell, or a transistor.

19. A dry film structure prepared by the composition of claim 1.

20. A process for preparing a dry film structure, comprising:
(a) coating a carrier substrate with the composition of claim 1 to form a coated composition;
(b) drying the coated composition to form a photosensitive polyimide layer; and
(c) optionally applying a protective layer to the photosensitive polyimide layer to form a dry film structure.

21. A process, comprising:
applying the dry film structure prepared by the process of claim 20 onto an electronic substrate to form a laminate, wherein the photosensitive polyimide layer in the laminate is between the electronic substrate and the carrier substrate.

22. A process of generating a dielectric film on a substrate having a copper pattern, comprising:
depositing the composition of claim 1 onto a substrate having a copper pattern to form a dielectric film, wherein the difference in the highest and lowest points on a surface of the dielectric film is at most about 2 microns.
